(19) United States
(12) Patent Application Publication
(10) Pub. No.: US 2010/0311405 A1
(43) Pub. Date: Dec. 9, 2010

(54) MOBILE PHONE AND METHOD FOR CONTROLLING VOLUME OF MOBILE PHONE

(75) Inventor: YUE-XIONG YANG, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (CN)

(21) Appl. No.: 12/570,626

(22) Filed: Sep. 30, 2009

(30) Foreign Application Priority Data
Jun. 5, 2009 (CN) 200910302955.1

(51) Int. Cl. H04M 3/00; H03G 3/00

(52) U.S. Cl. 455/419; 381/104

(57) ABSTRACT

A method is used for controlling volume in a mobile phone. The method includes the following steps. The mobile phone receives an input voice signal, and the mobile phone determines if the input voice signal is a digital signal. If the input voice signal is not digital signal, the input voice signal is converted to the digital voice signal. A volume of the digital voice signal is adjusted to a predefined volume if the volume of the digital voice signal is not equal to the predefined volume. The adjusted digital voice signal is output from the mobile phone.

### BACKGROUND

1. Technical Field

The disclosure generally relates to a mobile phone and a method for controlling the volume in a mobile phone during communications.

2. Description of Related Art

A phone user may make phone calls in different environments. For example, when a user receives a phone call in a meeting, the use may have to speak in a low voice, and if the caller is in a noisy environment, the caller may not be able to hear the low voice clearly.

### BRIEF DESCRIPTION OF THE DRAWINGS

FIG. 1 is a block view showing a component of a mobile phone, in accordance with embodiments.

FIG. 2 is a flowchart of a method for controlling volume in the mobile phone of FIG. 1.

FIG. 3 is a flowchart of a method for switching on the volume controller of the mobile phone of FIG. 1.

### DETAILED DESCRIPTION

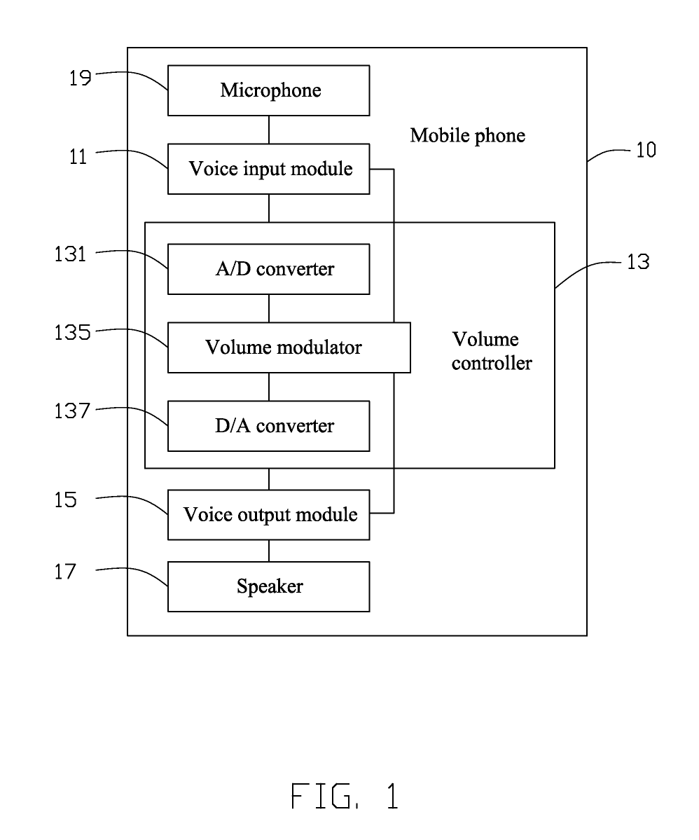

Referring to FIG. 1, a mobile phone 10 includes a voice input module 11, a volume controller 13, a voice output module 15, a microphone 19 and a speaker 17. The voice input module 11 can receive an input analog voice signal from the microphone 19 or from receive an input digital voice signal from a remote phone call via a mobile phone network, such as a global system for mobile communications (GSM) network during a phone call.

The volume controller 13 can adjust the input analog voice signal from the voice input module 11. The volume controller 13 includes an analog-to-digital (A/D) converter 131, a volume modulator 135 and a digital-to-analog (D/A) converter 137. If the input analog voice signal is received by the volume controller, the A/D converter 131 can convert the input analog voice signal into a digital voice signal. If the input digital voice signal is received by the volume controller, the input digital voice signal is directly output to the volume modulate module 135. The volume modulator 135 can adjust volume of the digital voice signal to a predefined volume. The predefined volume can be defined by a user. The predefined volume is in decibels. The D/A converter 137 can convert the adjusted digital voice signal into an output analog voice signal. In this embodiment, the volume modulator 135 can determine if the volume of the digital voice signal is equal to the predefined volume. If the volume of the digital voice signal is not equal to the predefined volume, the volume of the digital voice signal is adjusted to the predefined volume.

In another embodiment, the volume modulator 135 can determine if the volume of the digital voice signal is lower than the predefined volume. If the volume of the digital voice signal is lower than the predefined volume, the volume of the digital voice signal is adjusted to the predefined volume. If the volume of the digital voice signal is not lower than the predefined volume, then no adjustment is made. In other embodiments, the volume modulator 135 can enhance the volume of the voice signal when the original voice signal is little.

The voice output module 15 can output the adjusted digital voice signal to the speaker 17 when the input analog voice signal comes from the remote phone via the mobile phone network during a call, so that the speaker 17 can play the adjusted digital voice signal to the user directly. The voice output module 15 can also output the adjusted digital voice signal to the remote phone during a call, when the input analog voice signal comes from the microphone 19.

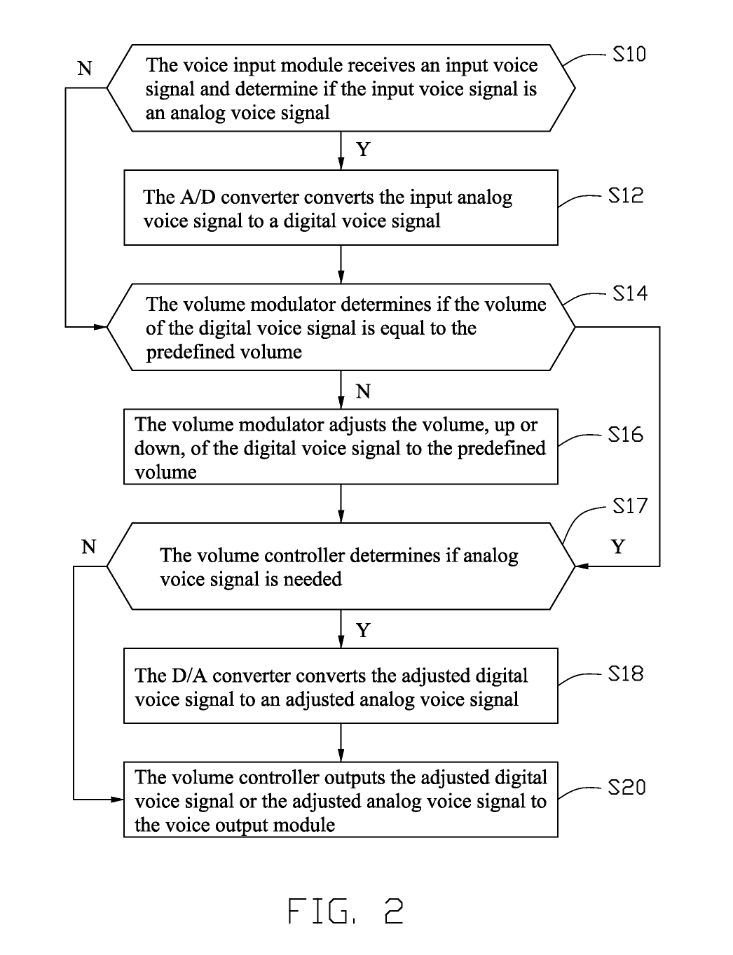

Referring to FIG. 2, a method for controlling volume in a mobile phone of one embodiment includes the following steps.

In step 10, the voice input module 11 receives an input voice signal. The input voice signal may come from the microphone 19 or from the remote phone call via the mobile phone network. The voice input module 11 can determine if the input voice signal is an analog or a digital voice signal. If the input voice signal is the analog voice signal, the voice input module 11 can transmit the analog voice signal to the A/D converter 131, and go to step 12. If the input voice signal is the digital voice signal, the voice input module 11 can transmit the analog voice signal to the volume modulator 135, and jump to step 14.

In step 12, the A/D converter 131 converts the input analog voice signal to a digital voice signal.

In step 14, The volume modulator 135 determines if the volume of the digital voice signal is equal to the predefined volume. If the volume of the digital voice signal is not equal to the predefined volume, go to step 16. If the volume of the digital voice signal is equal to the predefined volume, go to step 18.

In step 16, the volume modulator 135 adjusts the volume, up or down, of the digital voice signal to the predefined volume.

In step 17, the volume controller 13 determines if analog voice signal is needed, if yes, go to step 18; if no, jump to step 20.

In step 18, the D/A converter 137 converts the adjusted digital voice signal to an adjusted analog voice signal.

In step 20, the volume controller 13 outputs the adjusted digital voice signal or the adjusted analog voice signal to the voice output module 15. The voice output module 15 can output the adjusted analog voice signal or the adjusted digital voice signal to the speaker 17, an ear piece or the remote mobile phone.

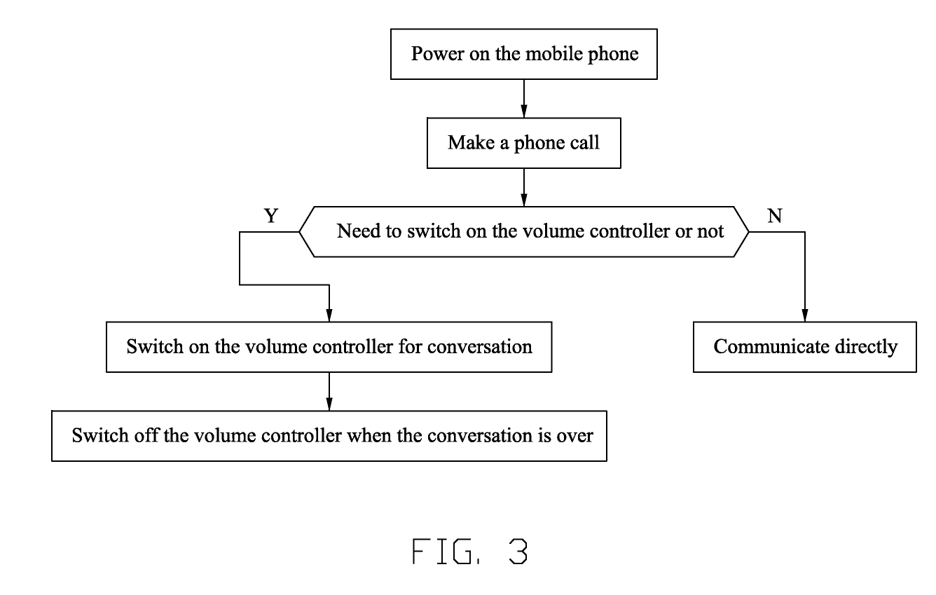

Referring to FIG. 3, the mobile phone 10 can simultaneously adjust a first input analog voice signal from the microphone 19 to the remote mobile phone and a second input analog voice signal from the remote mobile phone to the local speaker 17.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the invention to the full extent indicated by the broad general meaning of the terms in which the appended claims are expressed.

It is also to be understood that the above description and the claims drawn to a method may include some indication in reference to certain steps. However, the indication used is only to be viewed for identification purposes and not as a suggestion as to an order for the steps.

What is claimed is:

1. A method for controlling volume in a mobile phone, comprising:
receiving an input voice signal;
determining if the input voice signal is a digital signal, if the input voice signal is not digital signal, converting the input voice signal to the digital voice signal;
adjusting a volume of the digital voice signal to a predefined volume, if the volume of the digital voice signal is not equal to the predefined volume; and
outputting the adjusted digital voice signal from the mobile phone.

2. The method of claim 1 further comprising: converting the adjusted digital voice signal to an output analog voice signal.

3. The method of claim 1, wherein the adjusted digital voice signal is capable of being played by a speaker.

4. The method of claim 1, wherein the predefined volume is capable of being adjusted.

5. The method of claim 4, wherein the predefined volume is in decibels.

6. The method of claim 1 further comprising determining if the volume of the digital voice signal is lower than the predefined volume.

7. The method of claim 6, wherein if the volume of the digital voice signal is lower than the predefined volume, the volume of the digital voice signal is adjusted to the predefined volume.

8. The method of claim 6, wherein if the volume of the digital voice signal is equal or higher than the predefined volume, then no adjustment is made.

9. The method of claim 1, wherein the input voice signal is received from a remote phone via a mobile phone network during a call.

10. A mobile phone comprising:
a voice input module capable of receiving an input voice signal from a remote phone via a mobile phone network during a call;
a volume controller capable of adjusting the input voice signal, the volume controller comprising an analog-to-digital converter and a volume modulator; wherein the analog-to-digital converter is capable of converting the input voice signal to a digital voice signal if the input voice signal is not digital signal, and the volume modulator is capable of adjusting a volume of the digital voice signal to a predefined volume; and
a voice output module capable of outputting the adjusted digital voice signal.

11. The mobile phone of claim 10, wherein the volume controller module further comprises a digital-to-analog converter, the digital-to-analog converter is capable of converting the adjusted digital voice signal into an output analog voice signal, and the voice output module is capable of outputting the output analog voice signal.

12. The mobile phone of claim 11 further comprising a speaker, the speaker is capable of playing the output analog voice signal.

13. The mobile phone of claim 10, wherein the predefined volume is capable of being adjusted.

14. The mobile phone of claim 13, wherein the predefined volume is in decibels.

15. The mobile phone of claim 10, wherein the volume modulator is capable of determining if the volume of the digital voice signal is lower than the predefined volume.

16. The mobile phone of claim 15, wherein if the volume of the digital voice signal is lower than the predefined volume, the volume of the digital voice signal is capable of being adjusted up to the predefined volume.

17. The mobile phone of claim 15, wherein the volume of the digital voice signal is equal or higher to/than the predefined volume, then no adjustment is made.
